(19) United States
(12) Patent Application Publication
(10) Pub. No.: US 2010/0044871 A1
(43) Pub. Date: Feb. 25, 2010

(54) SEMICONDUCTOR DEVICE, DISPLAY DEVICE, AND ELECTRONIC DEVICE

(76) Inventors: Tatsuya Katoh, Osaka (JP); Satoru Kudose, Osaka (JP); Tomokatsu Nakagawa, Osaka (JP)

Correspondence Address: HARNESS, DICKEY & PIERCE, P.L.C., P.O. BOX 8910, RESTON, VA, 20195, US

(21) Appl. No.: 12/312,030

(22) PCT Filed: Sep. 28, 2007
(86) PCT No.: PCT/JP2007/069104

§ 371 Date: Apr. 23, 2009

(30) Foreign Application Priority Data
Oct. 26, 2006 (JP) 2006-291809

(51) Int. Cl. H01L 23/48

(52) U.S. Cl. 257/773; 257/E23.01; 257/797

(57) ABSTRACT

In order to attain, in a semiconductor device in which a semiconductor element is mounted, formation of a mark of a relatively large size which is easily recognizable by the naked eye or a machine, and which can apply a code system containing enough amount of information for tracing a manufacturing history, a semiconductor device according to the present invention includes an interposer electrically connected to a semiconductor element, which semiconductor device has a mark for displaying at least predetermined information relevant to the semiconductor element.

### TECHNICAL FIELD

The present invention relates to a semiconductor device in which a semiconductor element reduced in size is mounted, and a display device and an electronic device each of which includes the semiconductor device.

### BACKGROUND ART

A liquid crystal display device has been adopted in various devices such as a television, a monitor for a personal computer, and a mobile phone. Due to an increase in the amount of information that is required to be displayed, in the recent years, achievement of high-definition and high-performance have been advanced for the liquid crystal display device. Accordingly, further multi output has been requested from a liquid crystal driver which is a semiconductor element to be provided in the liquid crystal display device. In response to this, reduction in size of a driver circuit, fine pitching of a bump provided on a chip of the semiconductor element, and the like have been carried out so as to attain further multi output by the liquid crystal driver while suppressing increase in chip size.

Such semiconductor element that has been made as multi output is mounted in a TCP (Tape Carrier Package), a COF (Chip On Film) type package, and the like that allow easy forming of a fine pitch terminal (lead). The TCP and COF type packages are both packages in which a semiconductor element is directly flip chip bonded to a metal patterned inner lead formed on a tape carrier. The inner leads of the TCP and the COF are different in a point that, the inner lead of the TCP is a flying lead provided projecting out from a through hole (device hole) formed on a tape material, whereas the inner lead of the COF is provided on the tape material. Since the inner lead of the COF type package is supported by the tape material, it is possible to further reduce thickness of lead wiring. Thus, the COF type package is suitable for fine pitch lead formation.

While further reduction of chip size has been demanded for due to a request for low cost and to save resources, bounds of inner lead pitch in the package are starting to limit the reduction of the chip size. One example of a reason why the fine pitching of the inner lead becomes limited is described below. With COF and TCP type packages, when the semiconductor element is flip chip bonded to the tape carrier, a bump of the semiconductor element and the inner lead are bonded together by thermal compression. Since heat deformation occurs to the tape carrier at this time, it is required to provide a margin for a smallest pitch of the inner lead to a degree in which a disposition of a bump position on the semiconductor element and a lead position on the tape carrier does not occur caused by the deformation. This limits the reduction to the smallest pitch. A connection terminal (bump) that is formed on the semiconductor element is provided on a chip periphery of the semiconductor element at a same pitch as the inner lead on the tape carrier to which the bump is connected. Hence, even if a circuit area is reduced, an area for providing this connection terminal in a pitch not less than a predetermined measure is required on the semiconductor element. As a result, the reduction of the chip size is limited.

One method for solving such a problem is a method in which a semiconductor element is connected to a circuit board via an intermediate substrate (interposer), as disclosed in Patent Literature 1. FIG. 6 is a cross sectional view of a semiconductor device quoted from Patent Literature 1. A semiconductor element 101 is interconnected with an interposer 102 by flip chip bonding, and further the interposer 102 is interconnected with an electrode pattern 104 of a circuit board 120 by bump bonding. Electrodes 108 on the interposer 102 to which the semiconductor 101 is connected are formed so as to have a same fine pitch as electrodes 110 of the semiconductor element 101, and electrodes 109 to which the circuit board 120 is connected are formed to be in accordance with an electrode pitch of the electrode pattern 104 of the circuit board 120. The electrodes 108 to which the semiconductor element 101 is connected and the electrodes 109 to which the circuit board 120 is connected are connected to corresponding electrodes by wire bonding on the interposer 102. Note that, a tape carrier may be used as the circuit board 120.

A material that has sufficiently small thermal flexibility can be selected for the interposer 102; hence the limitation caused by the thermal deformation is minor and the pitch of the electrodes 108 to which the semiconductor element 101 is connected can be more finely pitched as compared to an electrode pitch that may be formed on the circuit board 120. Namely, by mediating the interposer 102 made of a material having a small thermal flexibility, it is possible to mount, in a package, a semiconductor element 101 having a further finely pitched connection terminal which exceeds the limit of the electrode pitch that may be formed on the circuit board 120.

This allows relaxation of the foregoing problem that the reduction in chip size is limited in order to provide an area of the connection terminal. As a result, reduction in size of the semiconductor element 101 is possible. Particularly, when an Si substrate is used as the interposer 102, the interposer 102 can be formed in an Si wafer process which is the same manufacturing process as the semiconductor element. Thus, it is possible for the electrodes 108 to which the semiconductor element 101 is connected to be formed in a fine pitch of an LSI level similarly to the semiconductor element 101. This is extremely effective for the reduction in size of the semiconductor element 101.

On the other hand, the semiconductor device in which the semiconductor element is mounted requires to have a mark provided at a predetermined position on the semiconductor device. This mark is a code constituting a plurality of letters representing unique information for identification of a product, such as a manufacturing company, name of product, and further a lot and a date of manufacture. In the semiconductor device of a film mounting type such as the COF and TCP, mark formation (marking) is generally carried out by utilizing a flat surface of a back surface of the semiconductor element that is flip chip mounted. For example, such examples are described in Patent Literatures 2 through 4.

In the semiconductor device described in FIG. 6 also, in which the semiconductor 101 is connected to the circuit board 120 via the interposer 102, a mark 105 is formed on a back surface 112 of the semiconductor element 1 mounted face down to the interposer 102, that is, on a reverse side of a surface on which a circuit is formed.

### Citation List

Patent Literature 1

Japanese Patent Application Publication, Tokukai, No. 2004-207566 A (Publication Date: Jul. 22, 2004)

Patent Literature 2

Japanese Patent Application Publication, Tokukaisho, No. 63-263748 A (Publication Date: Oct. 31, 1988)

Patent Literature 3

Japanese Patent Application Publication, Tokukaihei, No. 4-53249 A (Publication Date: Feb. 20, 1992)

Patent Literature 4

Japanese Patent Application Publication, Tokukai, No. 2005-203696 A (Publication Date: Jul. 28, 2005)

### SUMMARY OF INVENTION

However, in recent years, further reduction in design rules have been advancing; a chip size of the semiconductor element has become reduced in size, simultaneously. Because of this, it is becoming difficult to mark letters on the back surface of the semiconductor element at a size easily recognizable by the naked eye or a machine. Hence, hindrance occurs in reading the mark for confirmation and management of components, in an assembling step of a product that uses, as a component, the semiconductor device including the semiconductor element. Moreover, in order to attain further high quality management, the semiconductor device requires to have traceability of a mark which allows tracing a history of a manufacturing process of the product. However, the number of letters contained in a mark code is limited due to the limit of the marking area. Thus, a sufficient code system cannot be implemented.

Particularly, mounting a driver IC in a display device such as a liquid crystal display device frequently makes use of the TCP or COF type packages that are capable of multi-input and improvement in mounting density. Thus, such difficulty in recognition of the mark and insufficient traceability in the semiconductor device of such modes may cause effect to reliability of the product of the display device.

A semiconductor device according to the present invention is a semiconductor device including: an interposer, electrically connected to a semiconductor element, having a mark for displaying at least predetermined information relevant to the semiconductor element.

Alternatively, a semiconductor device according to the present invention is a semiconductor device including: a semiconductor element; an interposer electrically connected to the semiconductor element; and a circuit board electrically connected to the semiconductor element via the interposer, the interposer having a mark for displaying at least predetermined information relevant to the semiconductor element, on a reverse side of a surface to which the semiconductor element is connected.

A semiconductor device according to the present invention is a semiconductor device including an interposer electrically connected to a semiconductor element, the interposer having a mark for identifying the semiconductor element.

A semiconductor device according to the present invention is a semiconductor device including: a semiconductor element; an interposer electrically connected to the semiconductor element; and a circuit board electrically connected to the semiconductor element via the interposer, the interposer having a mark for identifying the semiconductor element, on a reverse side of a surface to which the semiconductor element is connected.

Moreover, the semiconductor device according to the present invention is arranged such that the circuit board is a tape carrier.

Furthermore, it is preferable for the interposer to be made of an Si substrate.

A semiconductor device according to the present invention is further arranged such that the interposer has wiring provided on a surface to which the semiconductor element is connected, and no wiring is provided on a reverse side of a region in which the mark is provided.

Moreover, the semiconductor device according to the present invention is arranged such that a driver IC for driving a display body that operates in response to an electric signal is used as the semiconductor element.

A display device according to the present invention includes: a semiconductor device including a driver IC, as the semiconductor element, for driving a display body that operates in response to an electric signal; and a display body that operates in response to an electric signal.

An electronic device according to the present invention includes one of the foregoing semiconductor devices.

In a semiconductor device according to the present invention, an interposer to which a semiconductor is connected has a larger area than that of the semiconductor. Hence, it is possible to attain a larger mark formation region. By displaying relatively large sized letters, it is possible to form a mark that is easily readable and well recognized. Moreover, limitation in the number of letters that can be marked is also relaxed. Thus, a code system which has good traceability containing enough amount of information to trace a manufacturing history can be easily applied.

Furthermore, a semiconductor device component which has a mark that is well recognized and has traceability that enables easy tracing of component history can be used in an electronic device such as a display device and the like which include the semiconductor device according to the present invention. Hence, it is possible to improve work reliability in a component assembling step, while also facilitating quality management of the product.

For a fuller understanding of the nature and advantages of the invention, reference should be made to the ensuing detailed description taken in conjunction with the accompanying drawings.

### BRIEF DESCRIPTION OF DRAWINGS

FIG. 1

FIG. 1 is a plan view illustrating one embodiment of a semiconductor device according to the present invention.

FIG. 2

FIG. 2 is a cross sectional view illustrating an essential part of the semiconductor device illustrated in FIG. 1, of a cross section on line A-A′.

FIG. 3

FIG. 3 is an explanatory view illustrating an example of a method for manufacturing a semiconductor device according to the present invention.

FIG. 4

FIG. 4 is a perspective view illustrating an arrangement in accordance with one embodiment of a display device according to the present invention.

FIG. 5

FIG. 5 is a cross sectional view illustrating an essential part of an arrangement of another embodiment of a semiconductor device according to the present invention.

FIG. 6

FIG. 6 is a cross sectional view illustrating an essential part of an arrangement of a conventional semiconductor device.

### DESCRIPTION OF EMBODIMENTS

One embodiment of a semiconductor device in accordance with the present invention is described below with reference to the attached drawings. The following description adds various limitations that are technically preferable for implementing the present invention, however the scope of the present invention is not limited to the following embodiment and drawings.

### First Embodiment

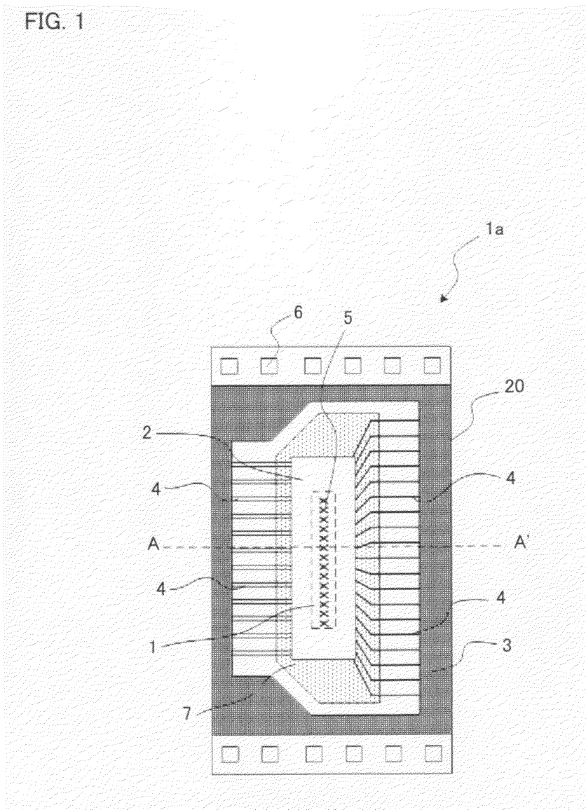

FIG. 1 is a plan view illustrating a liquid crystal driver mounting package, which is one embodiment of a semiconductor device according to the present invention.

A liquid crystal driver mounting package 1a of the present embodiment is a COF type package in which a semiconductor element (liquid crystal driver) 1 is electrically connected to a circuit board (tape carrier) 20 via an interposer 2. In FIG. 1, the liquid crystal driver 1 is provided on a back surface of the interposer 2. Thus, a position of the liquid crystal driver 1 which actually cannot be seen is shown by a dotted line.

A part illustrated in FIG. 1 is one unit of a long tape carrier, which one unit constructs one package. The tape has sprocket holes 6 on both side sections of the tape, for transferring this long tape. The tape carrier is constructed of a film material 3 whose main component is polyimide, wiring pattern 4 made of copper foil and provided on one side of the film material 3, and resist resin 7 provided for protecting the wiring pattern 4. One part of the wiring pattern 4 is exposed from the resist resin 7; an inner lead to be connected to the interposer 2 and an outer lead to be connected to an external circuit are formed by use of the exposed wiring pattern 4.

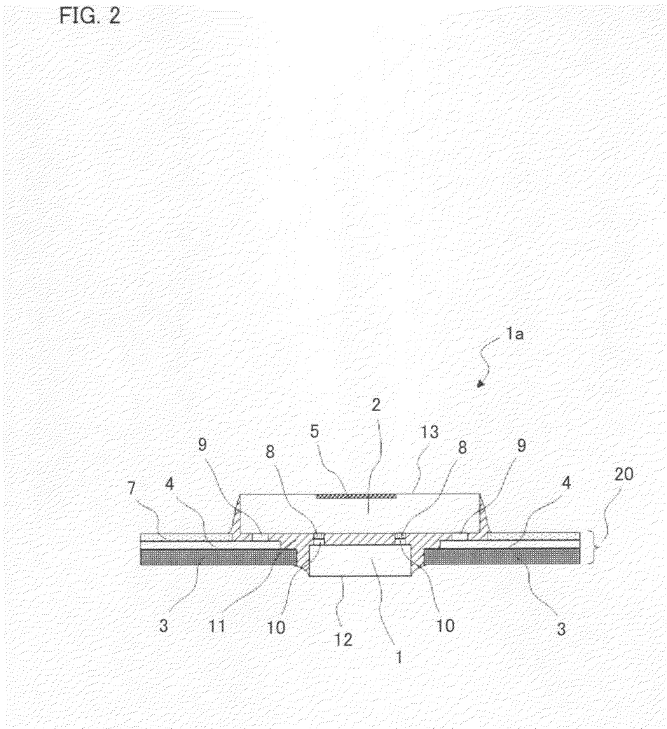

FIG. 2 is a cross sectional view illustrating a cross sectional state of the liquid crystal driver mounting package 1a illustrated in FIG. 1 on cross section line A-A′. The interposer 2 is connected to the inner lead that is formed by use of the exposed part of the wiring pattern 4 formed on the film material 3 from the resist resin 7. The liquid crystal driver 1 is connected to the interposer 2 by flip chip bonding. The interposer 2 is made of an Si substrate which has Al wiring, and on its surface with the wiring, semiconductor-element-connecting bump electrodes 8 for interconnecting with the liquid crystal driver 1 and circuit-board-connecting bump electrodes 9 for interconnecting with the tape carrier 20 are formed. The semiconductor-element-connecting bump electrodes 8 and corresponding circuit-board-connecting bump electrodes 9 are connected together via the Al wiring provided on the interposer 2. The semiconductor-element-connecting bump electrodes 8 and the circuit-board-connecting bump electrodes 9 are Au bumps.

The liquid crystal driver 1 and the interposer 2 are connected in such a manner that Au bumps 10 provided on the liquid crystal driver 1 are aligned so as to correspond to the semiconductor-element-connecting bump electrodes 8; then the Au bumps 10 and the semiconductor-element-connecting bump electrodes 8 are interconnected by thermal compression. The interposer 2 and the film material 3 are interconnected in such a manner that the circuit-board-connecting bump electrodes 9 on the interposer 2 and the wiring pattern 4 on the film material 3 are interconnected by Au—Sn bonding.

A thermosetting resin 11 is injected so as to cover interconnecting sections of the liquid crystal driver 1 and the interposer 2, and interconnecting sections of the interposer 2 and the film material 3. The thermosetting resin 11 reinforces these connections, and meanwhile obtains moisture resistance of the liquid crystal driver 1 and the circuit surface of the interposer 2. Since a back surface 12 of the liquid crystal driver 1 and a back surface 13 of the interposer 2 do not necessarily require protection, the arrangement has a flat back surface exposed, which is not covered by the thermosetting resin 11.

A mark 5 is formed by laser marking, on the back surface 13 of the interposer 2. The interposer 2 has a larger area than that of the liquid crystal driver 1. Hence, it is possible to make a marking of a larger sized letter as compared to conventionally forming a mark on the back surface 12 of the liquid crystal driver 1. Hence, it is possible to have a larger maximum number of letters that can be marked. Furthermore, it is difficult for reduction in area of a back surface flat section caused by crawling up of the thermosetting resin 11 to occur with the interposer 2, as compared to the liquid crystal driver 1. Thus, it is possible to stably carry out the marking.

This thus enables formation of an easily readable mark 5 even with a liquid crystal driver mounting package in which a liquid crystal driver reduced in size is mounted. Hence, it is possible to improve mark recognition. Moreover, a limit in the number of letters that can be marked is also relaxed. Thus, it is possible to easily use a code system which has good traceability, which contains a sufficient amount of information to trace the manufacturing history.

Furthermore, since the liquid crystal driver 1 which is a functional element is not marked, it is possible to avoid occurrence of malfunction caused by damage from (i) heat applied and (ii) engraving, in a formation step of the mark 5. Even in the case where a formation method of the mark 5 is ink marking by use of a stamp, an impact by the stamp will not be applied to the liquid crystal driver 1. Therefore, the cause for the occurrence of malfunction is reduced.

Moreover, the mark 5 may be formed on the back surface 13 of the interposer, by avoiding a region reverse to a region in which wiring is formed on a front surface (surface on which the liquid crystal driver 1 is connected). Confirmation of whether or not the wiring on the interposer in the liquid crystal driver mounting package is disconnected may be determined by carrying out an inspection with infrared light that transmits through Si and the like from a back surface 13 side of the interposer. When the mark is provided on a reverse side of the region in which the wiring of the interposer is provided, the infrared light becomes diffused at the marked part. This may cause difficulty in determining whether or not the wiring is disconnected. On the other hand, formation of the mark on a reverse side of a region in which the wiring on the interposer is not provided makes it easy to observe, by use of the infrared light, whether or not the interposer wiring has any disconnection.

Note that, a plate-shaped interposer having the wiring as illustrated in the present Example may at times be called an interposer substrate.

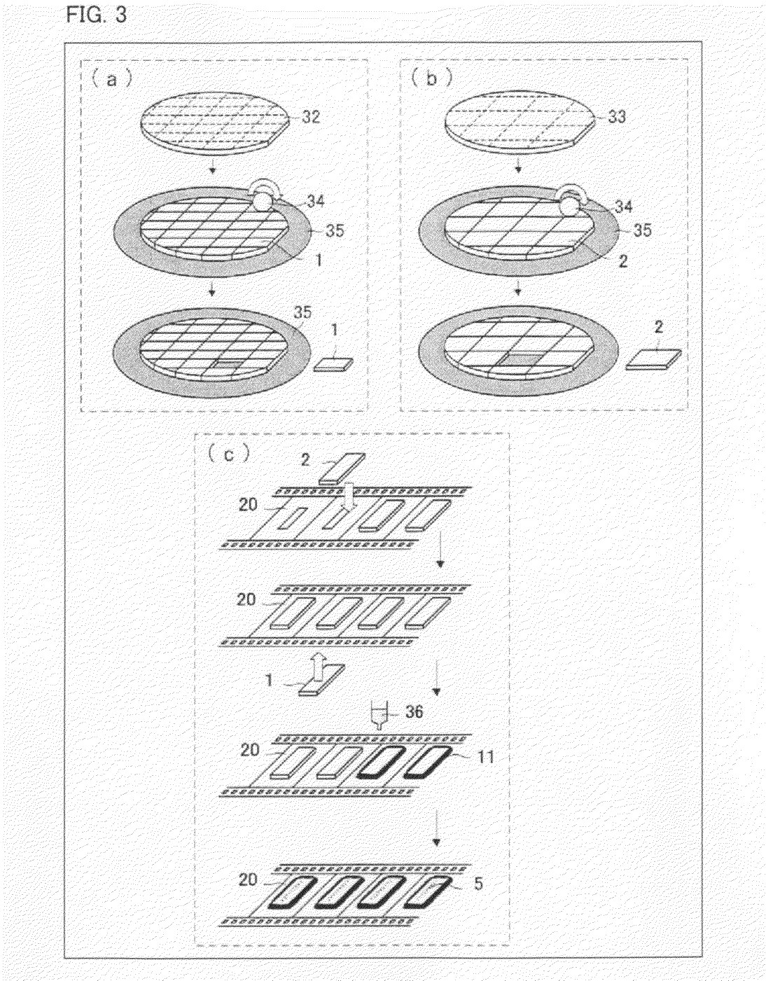

FIG. 3 is a view illustrating one example of a manufacturing process of the liquid crystal driver mounting package 1a. Note that, arrangements that are common to FIGS. 1 and 2 have the same reference signs as in FIGS. 1 and 2 attached thereto, and these reference signs may be quoted also in the descriptions.

First, as illustrated in dotted box (a) in FIG. 3, a driver wafer 32 on which a liquid crystal drive circuit and the like that serve as the liquid crystal driver are patterned is diced so as to form individual chips, thereby forming the liquid crystal driver 1. A conventional method may be employed for dicing the driver wafer 32; for example, the driver wafer 32 may be placed on a mounting board 35 and diced to a predetermined chip size by use of a dicing blade 34. Similarly to this, an interposer wafer 33 is diced so as to form individual chips to form the interposer 2 as illustrated in dotted box (b) in FIG. 3. On the interposer wafer 33, the semiconductor-element-connecting bump electrodes 8, the circuit-board-connecting bump electrodes 9, and the wiring are patterned.

A package mounting step of the liquid crystal driver is illustrated in dotted box (c).

Each of the interposers 2 that are made into individual chips is connected to the tape carrier 20 in such a manner that the circuit-board-connecting bump electrodes 9 and the inner lead of the tape carrier 20 are aligned, respectively. The Au bumps 10 of the liquid crystal driver 1 are aligned to the semiconductor-element-connecting bump electrodes 8, respectively, which semiconductor-element-connecting bump electrodes 8 are provided on the interposer 2 mounted on the tape carrier 20. The semiconductor-element-connecting bump electrodes 8 and the Au bumps 10 are then bonded by thermal compression, thereby establishing an electrical connection with the liquid crystal driver 1.

Thereafter, in order to protect and reinforce the connecting section, the thermosetting resin 11 is injected from a dispenser 36 to the bonded sections of the interposer 2 and the liquid crystal driver 1, and of the tape carrier 20 and the interposer 2, so as to seal the bonded sections. Finally, the mark 5 containing a plurality of letters for identifying a manufacturing company, a product name, a manufacturing lot, a manufacturing date, and the like, is formed on a back surface of the interposer 2 by laser marking. As such, the liquid crystal driver mounting package 1a is attained. Conventionally known methods such as ink marking using a stamp or an inkjet method may also be selected as the marking method.

In the present embodiment, a liquid crystal driver mounting package of a tape carrier type was used as an example in the description. However, the semiconductor device of the present invention is not limited to this mounting package. That is to say, various modifications are possible within the scope of the claims, for example, a driving element for a plasma display body or an EL (electroluminescence) display body, or a mounting package for an element mounted inside a device such as various handheld electronic devices. Moreover, in a case where it is also possible to make a mark on the semiconductor element, the marking may be made on both the interposer and the semiconductor element.

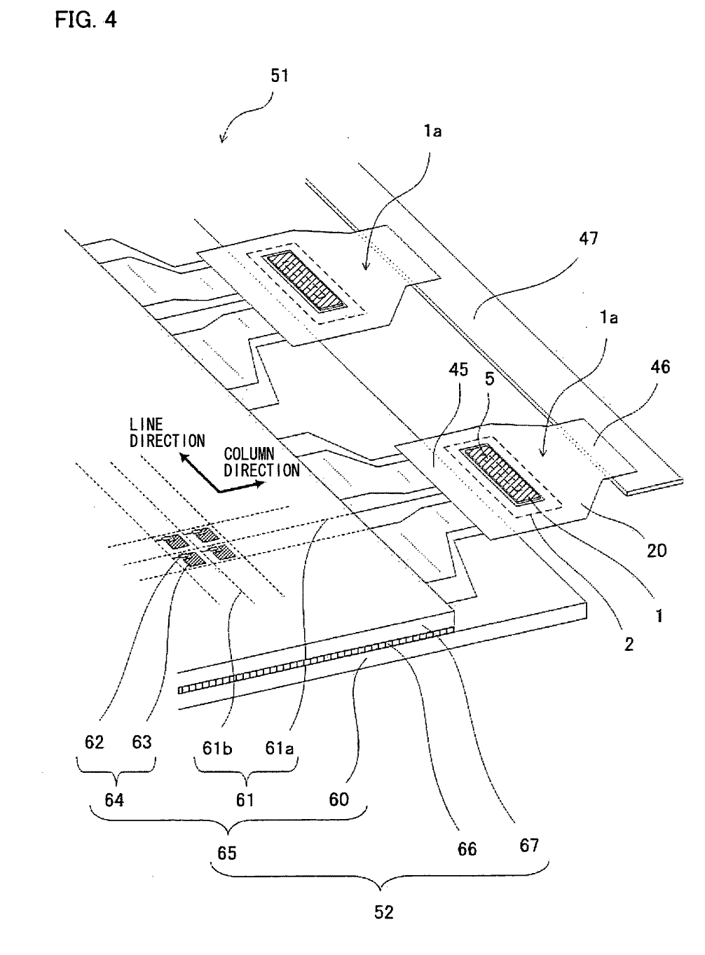

The following description explains a liquid crystal driver mounting display device (display device) including the liquid crystal driver mounting package 1a according to the present embodiment, with reference to FIG. 4. Note that the liquid crystal driver mounting display device is used for multiple purposes such as display of letters and images, or sun-sensoring of an illumination or a window that illuminate various colors.

FIG. 4 is a perspective view illustrating an arrangement of a liquid crystal driver mounting display device which is one embodiment of the present invention. A liquid crystal driver mounting display device 51 according to the present embodiment includes liquid crystal display means (display body) 52 and the liquid crystal driver mounting package 1a, as illustrated in FIG. 4.

The liquid crystal driver mounting package 1a is a liquid crystal driver mounting package in which a liquid crystal driver 1 is mounted in a tape carrier 20 via an interposer 2, and which has a mark 5 formed on a back surface of the interposer 2. In FIG. 4, the liquid crystal driver mounting package 1a is illustrated from a direction from which the liquid crystal driver 1 is visible as an upper surface; and the mark 5 is formed on the back surface of the interposer 2 (shown by dotted lines) provided on a back side of the liquid crystal driver 1. The tape carrier 20 has an output terminal section 45 and an input terminal section 46.

The liquid crystal display means 52 is arranged so as to include an active matrix substrate 65, a liquid crystal layer 66, and a counter substrate 67 having a counter electrode.

The active matrix substrate 65 has, as illustrated in FIG. 4, a glass substrate 60, and signal wiring 61, pixels 64 and the like which are formed on the glass substrate 60. Each of the pixels 64 is constructed of: a thin film transistor (hereinafter referred to as TFT) 62 which is a switching element; a pixel electrode 63; and the like. The pixels 64 are arranged in XY matrix form (two-dimensional matrix form). Data electrodes and gate electrodes of the TFT 62 are connected to respective data electrode lines 61a and gate electrode lines 61b.

Furthermore, the data electrode lines 61a and the gate electrode lines 61b extend in a column direction and a line direction of the active matrix substrate 65, respectively, and are connected to a plurality of liquid crystal drivers which drive each of the electrode lines. Note that the following description only explains an arrangement of the data electrode lines 61a illustrated in FIG. 4 for convenience, however it is obvious that the gate electrode lines 61b also have the same arrangement.

The data electrode lines 61a are extended to an end section of the glass substrate 60. At the end section, the data electrode lines 61a are connected to a drive signal outputting terminal provided in the output terminal section 45 of the liquid crystal driver mounting package 1a. This connection is accomplished by, for example, placing the drive signal outputting terminal provided at a predetermined pitch in the output terminal section 45 on top of a plurality of data electrode lines provided in the end section of the glass substrate 60 at a same pitch as the drive signal outputting terminal via an ACF (Anisotropic Conductive Film), and thermally compressing the two together.

On the other hand, signal inputting terminals provided in the input terminal section 46 of the liquid crystal driver mounting package 1a is connected to wiring provided on an external wiring substrate 47. The wiring on the external wiring substrate 47 supplies (i) control signals for display data and the like and (ii) power supply potentials. The control signals and the power supply potentials are transmitted to the liquid crystal driver 1 via the tape carrier 20 and the interposer 2.

The drive signals generated at the liquid crystal driver 1 based on the display data is outputted from the drive signal outputting terminal of the liquid crystal driver mounting package 1a via the interposer 2. This allows controlling lighting of the pixels 64 which react upon transmission of the drive signal to the data electrode lines 61a.

As described above, a liquid crystal driver mounting package according to the present invention enables formation of a mark which is well recognized, since the mark is easily readable due to its relatively large letter size even in a case where a liquid crystal driver of a reduced size is mounted in the package. Moreover, since it is also possible to relax a limit in the number of letters that can be marked, a code system having a good traceability is applicable to the mark, which code system contains enough amount of information for tracing a manufacturing history.

A liquid crystal driver mounting package component including a mark that has good recognition and traceability may be used; hence a liquid crystal driver mounting display device of the present invention is improved in work reliability in a component assembling step, and meanwhile makes quality management of the product easy. As a result, it is possible to attain high-performance and low cost of the liquid crystal driver mounting display device while ensuring sufficient reliability.

In the present embodiment, the glass substrate 60 is used in the active matrix substrate 65. However, the present invention is not limited to this, and may use a conventionally known substrate as long as the substrate is transparent. Moreover, in the present embodiment, a liquid crystal driver 1 is used as a driver for the data electrode lines. However, the present invention is not limited to this, and the liquid crystal driver 1 may be used as the driver for the gate electrode lines.

Furthermore, in the present embodiment, a description was given as a liquid crystal driver mounting display device arranged so as to drive a liquid crystal display body, however the display device of the present invention is not limited to the liquid crystal driver mounting display device. Various modifications are possible within the scope of the claims, such as an EL (electroluminescence) display body or a plasma display body.

### Second Embodiment

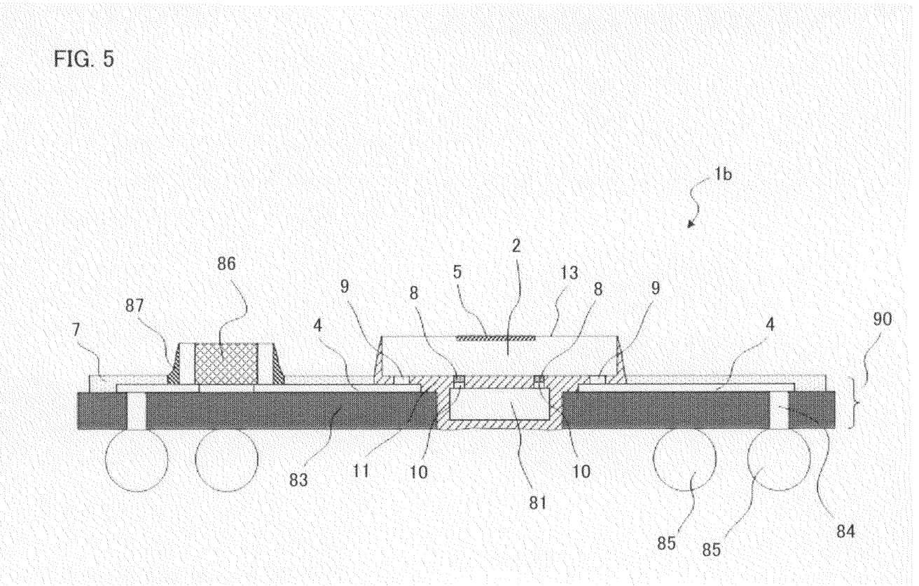

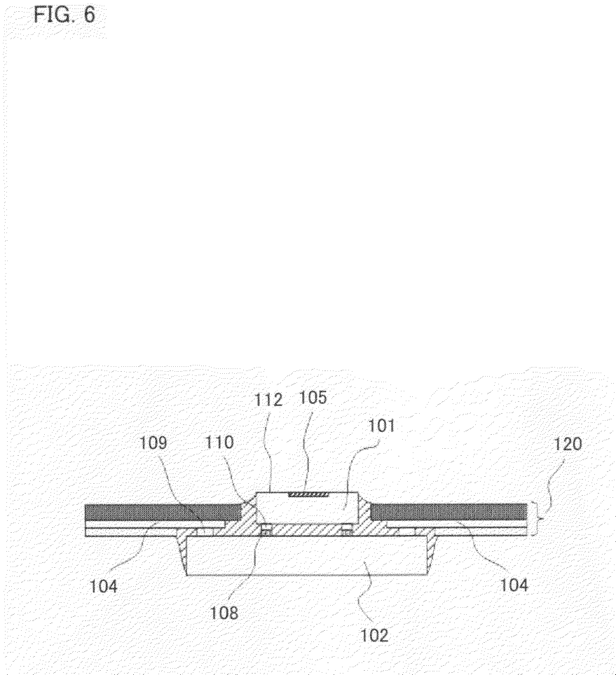

FIG. 5 illustrates an example of a mounting body of a BGA (Ball Grid Array) type in which a semiconductor element is mounted, as another example of a semiconductor device according to the present invention. Note that any arrangements which have the same function as the arrangements in the liquid crystal driver mounting package described before has the same reference sign attached thereto, and duplicating explanations will be omitted.

A semiconductor element (IC chip) 81 is interconnected with the interposer 2 by flip chip bonding, and furthermore, the interposer 2 is connected to a wiring pattern 4 provided on a circuit board 90, so as to be mounted in a BGA-type mounting body 1b.

The circuit board 90 is made of insulating material 83 such as glass epoxy resin or ceramic. The wiring pattern 4 provided on the insulating material 83 is connected to solder bumps 85 formed in a gridlike sequence on a reverse side of the insulating material 83, via respective via holes 84 which penetrate through the insulting material 83. The solder bumps 85 function as a terminal for connecting the BGA type mounting body 1b with further external circuit boards. A surface of the wiring pattern 4 is covered with resist resin 7; however, one part of the wiring pattern 4 is exposed from the resist resin 7, with which a connection lead is formed.

The wiring pattern 4 on the circuit board 90 composes one part of an external circuit of the IC chip 81, and a chip component 86 which is an external component is also connected to the wiring pattern 4. The chip component 86 can be connected to the wiring pattern 4 by use of solder 87, conductive paste, or the like. Modularization by including an external circuit and an external component into the package reduces a circuit area containing the external component, and meanwhile allows reduction of the number of terminals in the BGA type mounting body 1b. This contributes to reduction in size of a system which uses the BGA-type mounting body 1b.

The thermosetting resin 11 is injected to the connecting sections of the interposer 2 and the IC chip 81 and of the circuit board 90 and the interposer 2, so as to reinforce or protect the connecting sections. The back surface 13 of the interposer 2 reverse to the surface on which the IC chip 81 is mounted, is arranged so as to be exposed from the thermosetting resin 11. Moreover, the IC chip 81 is completely embedded in the thermosetting resin 11 inside a through hole (device hole) in the insulating material 83. Therefore, the IC chip 81 is arranged to be difficult to be exposed to an external environment.

The mark 5 is provided on the back surface 13 of the interposer 2. It is the same with the liquid crystal driver mounting package described in First Embodiment that such an arrangement allows obtainment of a large mark formation region, which enables to mark large sized letters that are easily readable and further to have an increased maximum number of letters that can be marked.

The BGA type mounting body 1b operates by having the external circuit board further connected thereto. Upon connection, since the IC chip 81 is positioned on a reverse side to a front surface side of the external circuit board, the IC chip 81 cannot be visualized from outside. Marking the identification information of the IC chip 81 on the back surface 13 of the interposer 2 allows easy verification of the identification information of the IC chip 81, even after the BGA type mounting body 1b is assembled to the external circuit board.

In the present embodiment, various semiconductor elements, such as a liquid crystal driver, a memory IC, a DSP, and the like may be suitably applied as the IC chip 81. Moreover, the circuit board 90 is not limited to a single layered board, and a multilayered board may also be applied.

As described above, First and Second Embodiments explained examples in which one interposer is mounted in one semiconductor device. However, it is obvious that the present invention attains the same effects also with an embodiment in which a plurality of interposers is mounted in one semiconductor device. Moreover, the present invention may also be applied to a semiconductor device in which a plurality of semiconductor elements is mounted in one interposer.

The interposer is not limited to a hard material such as the interposer made of the Si substrate shown in the present Example, and may be a flexible material such as tape material, or an elastic material. In addition, a shape of the interposer is not limited to a plate shape, and may be in various shapes in accordance with purpose, for example a prism shape, or a substantially round shape so as to suit a shape of a semiconductor element mounted surface.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

1-3. (canceled)

4. A semiconductor device comprising:
a semiconductor element;
an interposer electrically connected to the semiconductor element; and
a circuit board electrically connected to the semiconductor element via the interposer,
the interposer having a mark for identifying the semiconductor element, on a reverse side of a surface to which the semiconductor element is connected.

5. The semiconductor device as set forth in claim 4, wherein the circuit board is a tape carrier.

6. The semiconductor device as set forth in claim 4, wherein the interposer is made of an Si substrate.

7. The semiconductor device as set forth in claim 4, wherein the mark is an ink marking.

8. The semiconductor device as set forth in claim 4, wherein the mark is a laser marking.

9. The semiconductor device as set forth in claim 4, wherein the interposer has wiring provided on a surface to which the semiconductor element is connected, and no wiring is provided on a reverse side of a region in which the mark is provided.

10. The semiconductor device as set forth in claim 4, wherein the semiconductor element is a driver IC for driving a display body that operates in response to an electric signal.

11. A display device comprising:
a semiconductor device recited in claim 10; and
a display body that operates in response to an electric signal.

12. An electronic device comprising a semiconductor device recited in claim 4.
